(19) United States
(12) Patent Application Publication
(10) Pub. No.: US 2012/0224316 A1
(43) Pub. Date: Sep. 6, 2012

(54) Foldable carrying case for a tablet computer

(76) Inventor: Arthur M. Shulenberger, Millbrae, CA (US)

(21) Appl. No.: 13/039,752

(22) Filed: Mar. 3, 2011

(51) Int. Cl. H05K 7/00

(52) U.S. Cl. 361/679.09

(57) ABSTRACT

A carrying case for a tablet computer. The carrying case is foldable and provides protection for the tablet computer when closed. When open, the carrying case provides a stable support for operating the tablet computer. A keyboard, which can be removable, is also provided as part of the carrying case. Optional features including solar charging, stereo speakers, camera and removable data storage can also be incorporated into the carrying case.

### CROSS-REFERENCE TO RELATED APPLICATIONS

Not applicable.

### STATEMENT REGARDING FEDERALLY SPONSORED RESEARCH OR DEVELOPMENT

Not applicable.

REFERENCE TO A SEQUENCE LISTING, A TABLE, OR A COMPUTER PROGRAM LISTING COMPACT DISC APPENDIX

Not applicable.

### BACKGROUND OF THE INVENTION

The invention relates to tablet computers, carrying cases for tablet computers, keyboards and other accessories for tablet computers, and the like. A tablet computer is a computing device which is generally portable and hand-held, and is dominated in its design by its display and associated touch-screen interface. Tablet computers generally lack physical keyboards and when the user wishes to input text, the user activates a software-generated touch-screen keyboard for that activity.

Since it is not uncommon for tablet computer users to have the need to input text, physical keyboards that are compatible with tablet computers are manufactured and sold. The use of such prior art keyboards with tablet computers is problematic in a number of ways, such as: difficulty in carrying the keyboard and tablet computer together conveniently, setting up the combination of keyboard and tablet computer quickly, and providing protection to the tablet computer when it is carried with the keyboard.

### BRIEF SUMMARY OF THE INVENTION

The invention acts as a carrying case for a tablet computer and also provides a physical keyboard to the tablet computer user. When the invention is in the open configuration it supports the tablet computer in an ergonomic position relative to the invention's keyboard. In the open configuration, the tablet computer can be inserted or removed from the invention. When the invention is in the closed configuration it provides a convenient means of carrying the tablet computer and also protects the tablet computer. Some embodiments of the invention include solar charging to the tablet computer.

It is an object of the invention to provide a carrying case for a tablet computer that includes a physical keyboard. Another object of the invention is to support a tablet computer in an ergonomic relationship to the invention's built-in keyboard. A further object of the invention is to provide an electrical connection between a tablet computer and the invention's built-in keyboard. Yet another object of the invention is to provide solar charging for a tablet computer.

### BRIEF DESCRIPTION OF THE SEVERAL VIEWS OF THE DRAWINGS

FIGS. 1a through 1e are isometric views of the invention along with a tablet computer shown in a series of steps from closed to open, with and without the tablet computer inserted into the invention.

FIG. 2a is an isometric view of the invention in the open configuration. FIG. 2b is an exploded isometric view of the invention in the open configuration.

FIG. 3a is an isometric view of the keyboard section of the invention. FIG. 3b is an exploded isometric view of the keyboard section of the invention.

FIG. 4a is an isometric view of the tablet computer housing section of the invention. FIG. 4b is an exploded isometric view of the tablet computer housing section of the invention.

FIG. 5a is an isometric view of the rear support section of the invention. FIG. 5b is an exploded isometric view of the rear support section of the invention.

FIG. 6a is an isometric view of the rear support brace section of the invention. FIG. 6a is an exploded isometric view of the rear support brace section of the invention.

FIG. 7a is an isometric view of the docking connector assembly of the invention. FIG. 7b is an exploded isometric view of the docking connector assembly of the invention.

FIGS. 8a, 8b and 8d are orthogonal views of the docking connector assembly of the invention. FIG. 8c is a sectional view of FIG. 8a.

FIG. 9a is an isometric view of the rear support brace slide assembly of the invention. FIG. 9b is an exploded isometric view of the rear support brace slide assembly of the invention.

FIG. 10c is a front view of the tablet computer housing section of the invention. FIG. 10a is a sectional view of FIG. 10c. FIG. 10b is a detail view of FIG. 10a. FIG. 10d is a detail view of FIG. 10a.

### DETAILED DESCRIPTION OF THE INVENTION

Certain specific details are set forth in the following description and figures to provide a thorough understanding of various embodiments of the invention. Certain well-known details often associated with computing and computer cases are not set forth in the following disclosure, however, to avoid unnecessarily obscuring the various embodiments of the invention. Further, those of ordinary skill in the relevant art will understand that they can practice other embodiments of the invention without one or more of the details described below. Finally, while various methods are described with reference to steps and sequences in the following disclosure, the description as such is for providing a clear implementation of embodiments of the invention, and the steps and sequences of steps should not be taken as required to practice this invention. Instead, the following is intended to provide a detailed description of an example of the invention and should not be taken to be limiting of the invention itself. Rather, any number of variations may fall within the scope of the invention, which is defined by the claims that follow the description.

The present invention may be better understood, and its numerous objects, features, and advantages made apparent to those skilled in the art by referencing the accompanying drawings, wherein:

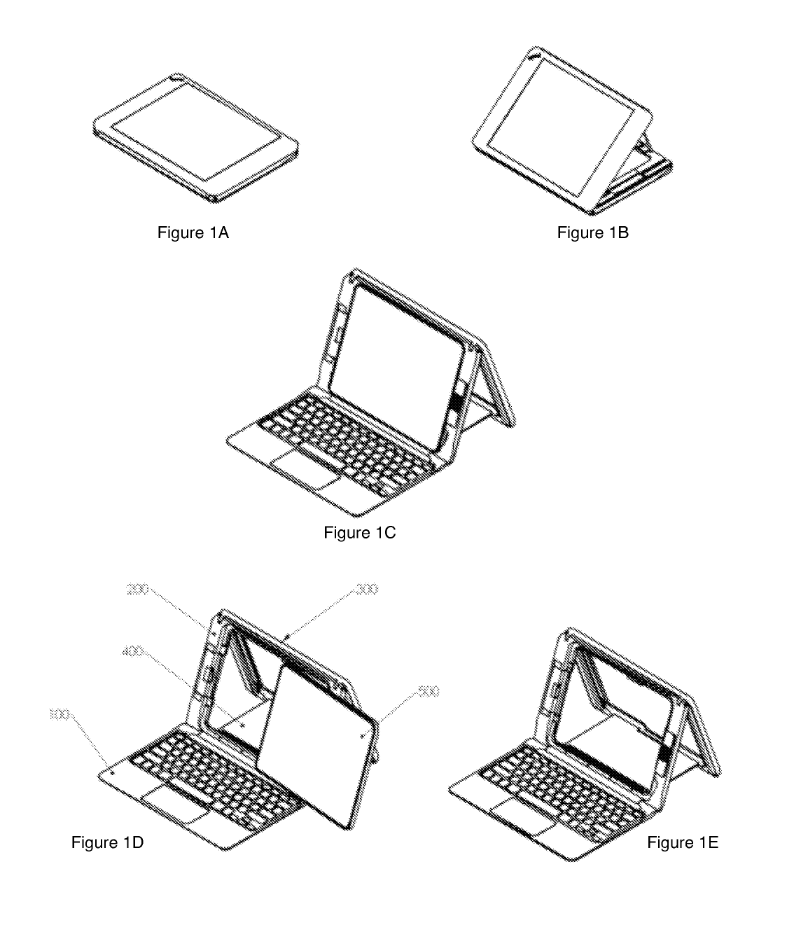

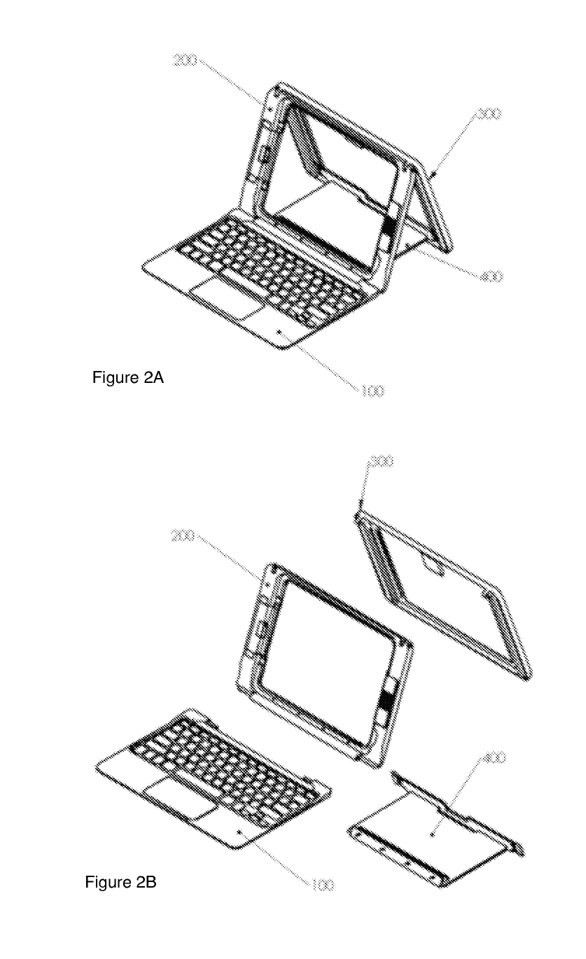

FIG. 1 illustrates a multifunctional carrying case for a tablet computer. In particular, FIG. 1 is comprised of five sub-figures, 1a through 1e, that show the basic design and functionality of the case in all the basic configurations from 1a fully closed to 1e fully deployed with tablet computer removed. FIG. 1d defines by number the four-hinged segments of the carrying case, as well as the removable tablet computer that integrates with the carrying case. The base member 100 contains the keyboard, trackpad and wiring connecting it with the frame member 200, providing electrical communication means. The frame member 200 comprises a tablet computer housing and docking connector, as well as wiring connecting it with the base member 100 and the rear support member 300, providing electrical communication means. The rear support member 300 contains a solar panel and wiring connecting it with the frame member 200, providing electrical communication means. The rear support member 300 provides structural support for the carrying case in its fully deployed state through a major flat surface. The link member 400 comprises a hinge lock assembly limiting the degree to which the carrying case opens through a pivotal motion limiting means. The functionality of the carrying case is designed around the tablet computer 500.

FIG. 1a shows the case in a fully closed configuration, wherein the outer surfaces of segments 100 and 300 serve as the outer shell of the case. FIG. 1b shows the case in a partially opened configuration, wherein the case is unlatched and segment 300 is hinged upwards, which results in the link member 400 hinging downward and sliding and locking into the frame member 200, in a fully extended position. FIG. 1c shows the case in a fully deployed configuration, wherein the frame member 200 has been hinged upwards from the base member 100 to a set vertical position defined by the link member 400 through a pivot axis and linear motion axis means. In this configuration the functionality of the case has been transformed from carrying case to laptop computer. FIG. 1d shows the fully deployed case with the tablet computer being removed from the housing. FIG. 1e shows the fully deployed case with the tablet computer completely removed.

FIG. 2a shows the case in its fully deployed state without the tablet computer and FIG. 2b shows the case with all subassemblies exploded. The base Member 100 contains the keyboard, trackpad and wiring connecting it with the frame member 200. The frame member 200 comprises a tablet computer housing, docking connector, and wiring connecting it with the base member 100 and the rear support member 300. The rear support member 300 contains a solar panel and wiring connecting it with the frame member 200. The link member 400 limits the degree to which the case opens.

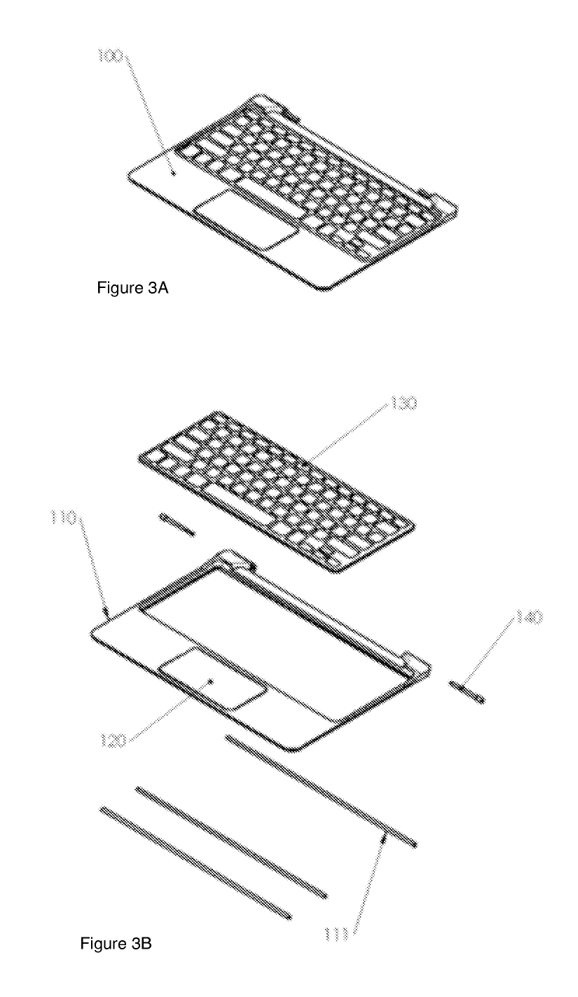

FIG. 3a shows the base member 100. FIG. 3b shows the base member 100 with all subassemblies exploded: the keyboard housing 110, the anti-skid pad 111, the trackpad 120, the keyboard 130, and the hinge pin 140. The anti-skid pad 111 is one of three anti-skid pads captured on the surface of the keyboard housing 110. The trackpad 120 can be removable, but in the current embodiment is an integral part of the keyboard housing 110. The keyboard 130 is removable in the current embodiment, but can be an integral part of the keyboard housing 110. The hinge pin 140 is one of two identical hinge pins, connecting the hinging detail in the keyboard housing 110 with the hinging detail in the frame member 200.

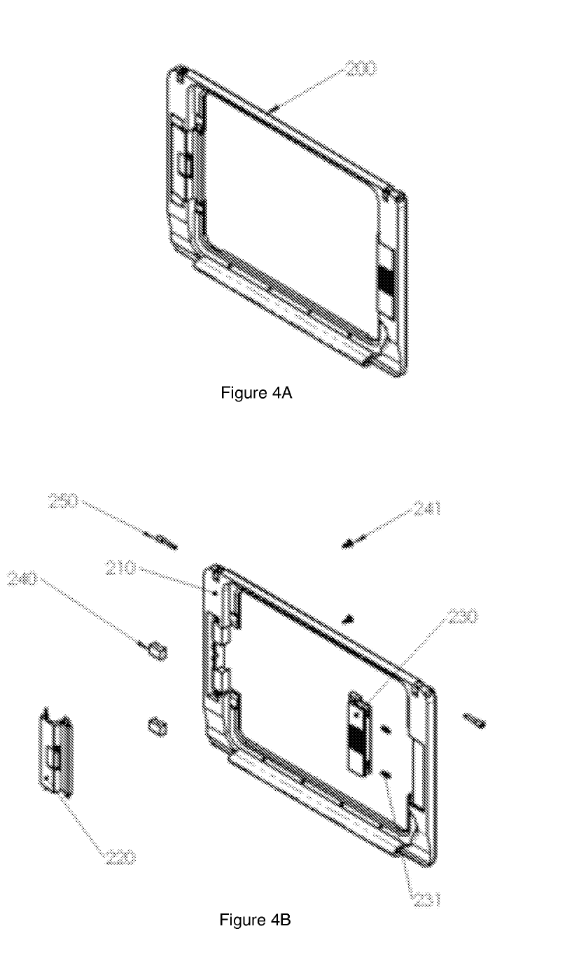

FIG. 4a shows the frame member 200. FIG. 4b shows the frame member 100 with all subassemblies exploded: the tablet computer housing body 210, the docking connector pivot assembly 220, the slide latch assembly 230, the two springs 231, the two pivot blocks 240, the two screws 241, and the two hinge pins 250. The two springs 231 work in concert with the slide latch assembly 230, providing a spring-loaded latching function. The two screws 241 attach the two pivot blocks 240 to the tablet computer housing body 220. The two hinge pins 250 connect the frame member 200 with the rear support member 300.

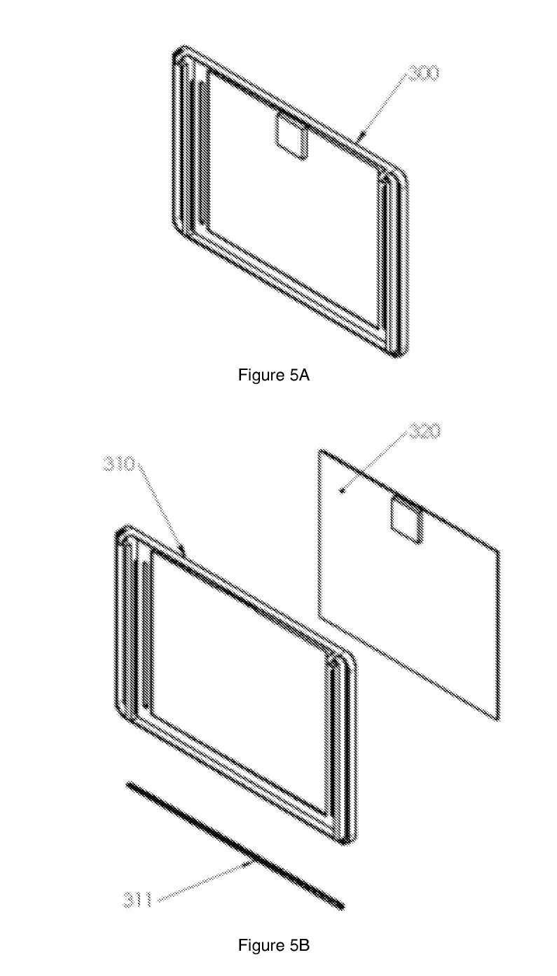

FIG. 5a shows the rear support member 300. FIG. 5b shows the rear support member 300 with all subassemblies exploded: the solar panel housing 310, the solar panel 320, and the anti-skid pad 311. The anti-skid pad 311 is captured on the surface of the rear support member 300.

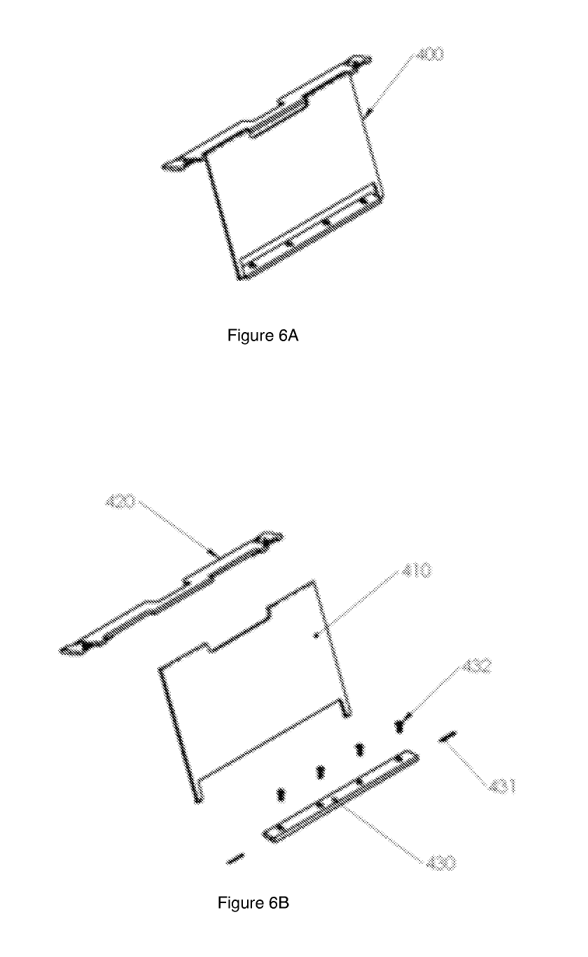

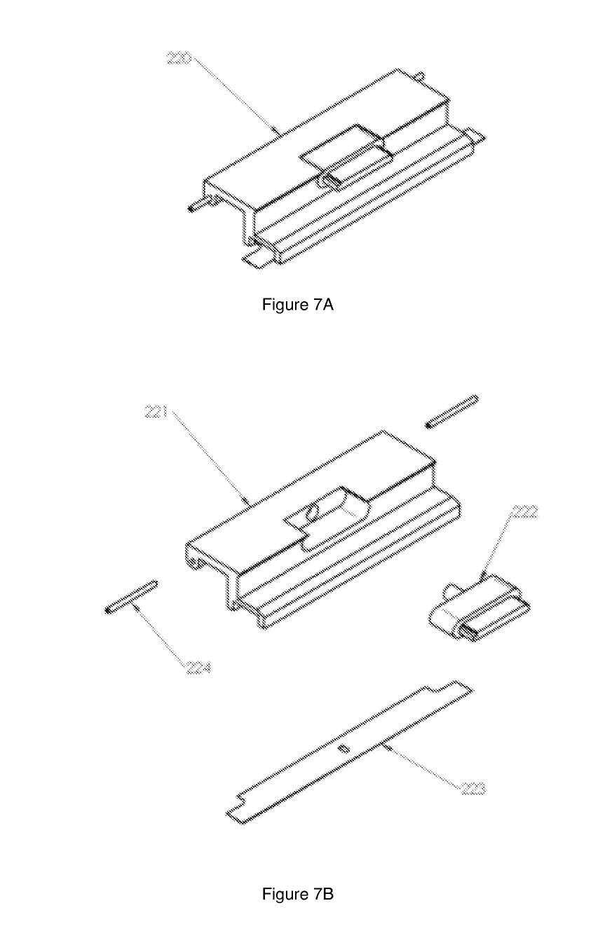

FIG. 6a shows the link member 400. FIG. 6b shows the link member 400 with all subassemblies exploded: the pivot plate 410, the pivot slide assembly 420, the pivot hinge assembly 430, the two pins 431, and the four screws 432. The pivot slide assembly 420 provides a linear motion guide means. The two pins 431 press into the pivot hinge assembly 430 through the holes in the pivot plate 410, creating a pivot point between the pivot plate 410 and the pivot hinge assembly 430. The four screws 432 connect the pivot plate 410 to the frame member 200.

FIG. 7a shows the docking connector pivot assembly 220. FIG. 7b shows the docking connector pivot assembly 220 with all subassemblies exploded: the docking connector pivot block 221; the docking connector 222; the flat metal spring 223, the two pins 224, and the two pivot blocks 240. The flat metal spring 223 has a locating feature aligning it with a protrusion and a channel on the underside of the docking connector pivot block 221. The two pins 224 press into the docking connector pivot block 221, connecting it with the two pivot blocks 240.

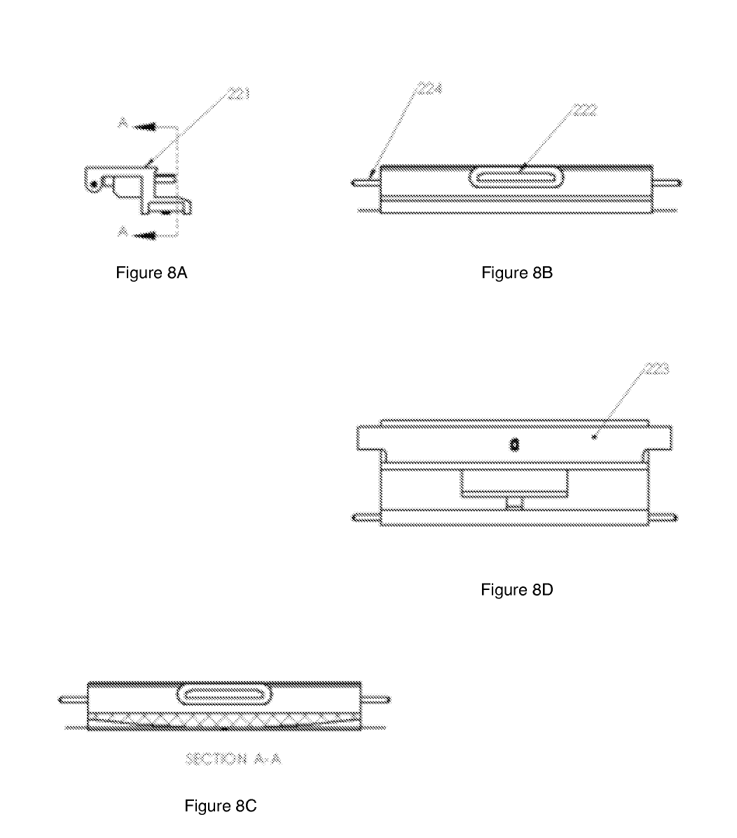

FIG. 8 has four sub-figures that clarify the relationships between parts in the docking connector pivot assembly 220. FIG. 8a, a bottom view of the docking connector pivot block 22, shows all associated parts in the docking connector pivot assembly 220 when they are in a locked position relative to the tablet computer housing body 210. FIG. 8b shows the same assembly parts shown in FIG. 8a from a side view, facing the position at which the tablet computer connects electrically with the docking connector pivot assembly 220. FIG. 8c (Section A-A), a section view of 8b, shows the curved surface that the flat metal spring 223 wraps around when it is assembled with the docking connector pivot block 221. FIG. 8c (Section A-A) also shows the two screws 241 that attach the two pivot blocks 240 to the tablet computer housing body 220. FIG. 8d presents an orthogonal view, relative to FIG. 8b, of the same assembly parts shown in FIG. 8b.

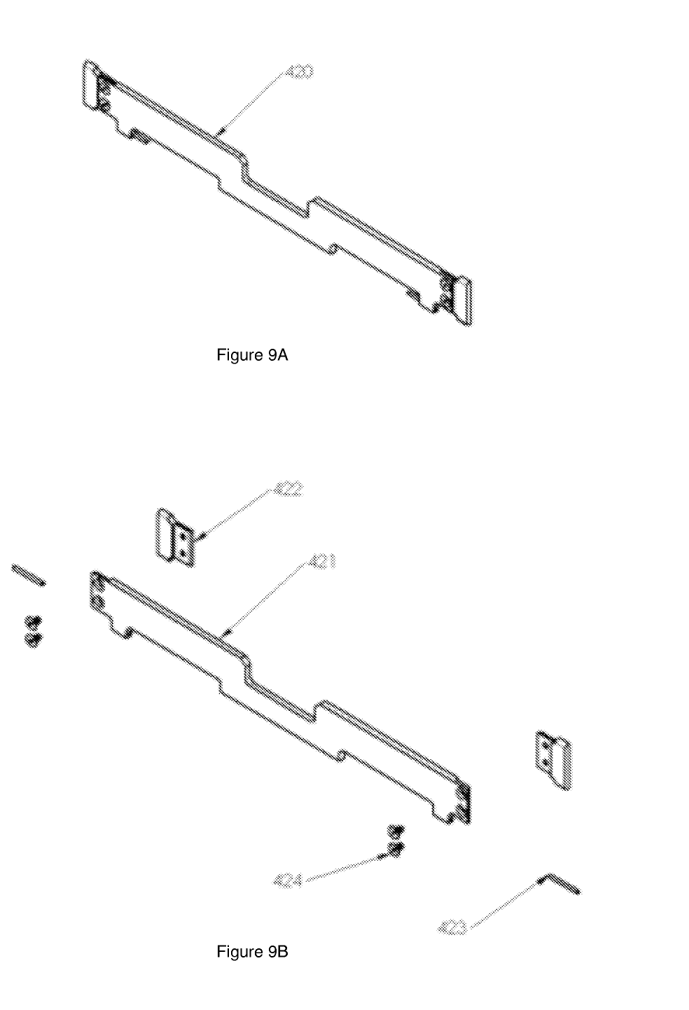

FIG. 9a shows the pivot slide assembly 420. FIG. 9b shows the pivot slide assembly 420 with all subassemblies exploded: the slider frame 421, the two slider blocks 422, and the two pivot pins 423. The two screws 424 connect the slider frame 421 with the two slider blocks 422. The slider frame 421 mounts the two slider blocks 422 into the slider tracks in the solar panel housing 310 with the two screws 424 attached. The two slider blocks 422 fit into the tracks located in the solar panel housing 310. The two pivot pins 423 connect the slider frame 421 with the link member 400.

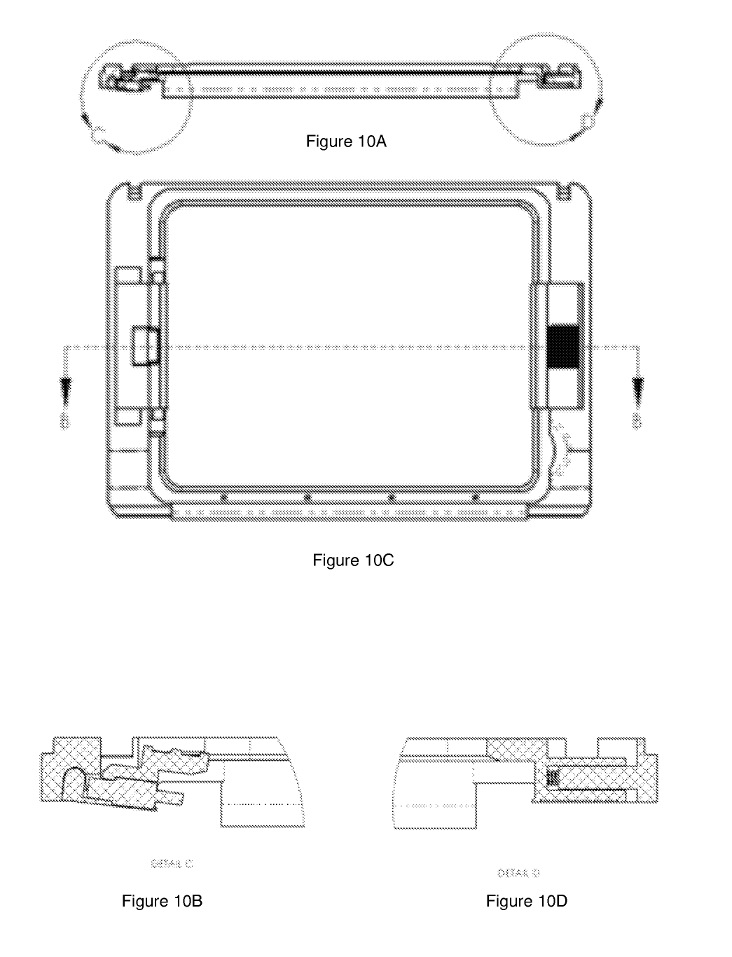

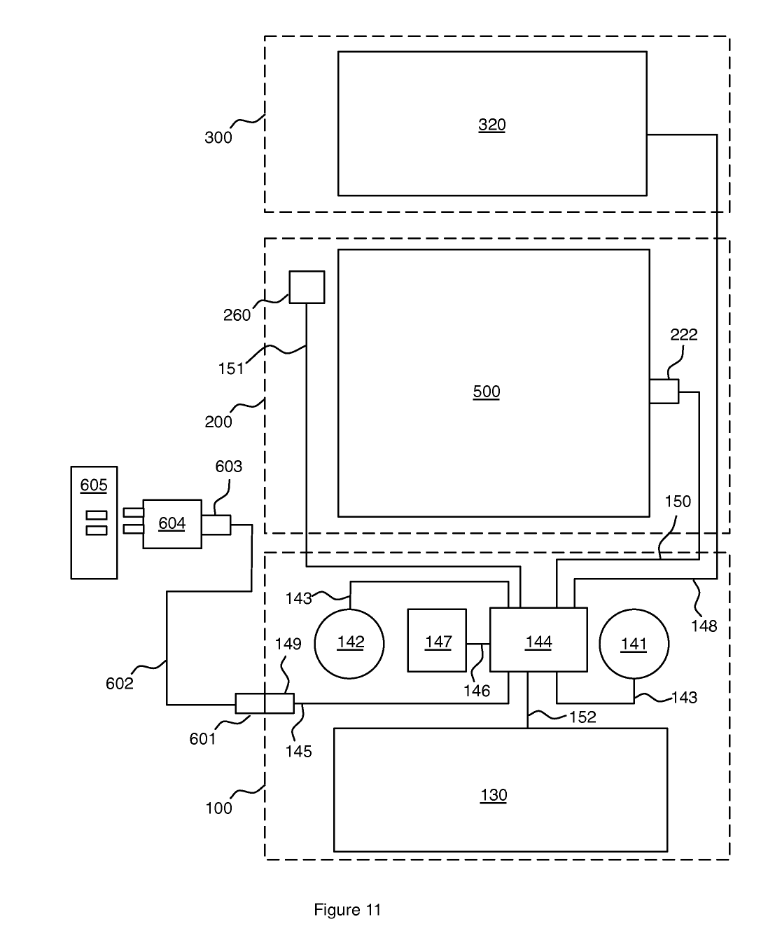

FIG. 10 comprises four sub-figures that detail features in the frame member 200. FIG. 10a (Section B-B) presents a section view of the frame member 200 shown in Section BB of FIG. 10c. FIG. 10b (Detail C) shows the connector and pivot assembly and presents a front view of the frame member 200. FIG. 10b shows the spring and latching assembly 10b (Detail D).

FIG. 11 shows the base member 100, the frame member 200, and the rear support member 300. FIG. 11 shows the electrical connectors and electrical wiring between carrying case members that enable all electrically powered integral and auxiliary functions. The solar panel 320 contained within the rear support member 300 connects directly through solar panel electrical wiring 148 to the PC board 144. The PC board 144 connects directly to the following listed parts: to the solar panel 320 through solar panel electrical wiring 148; to the battery 147 through battery connection wiring; to the keyboard 130 through keyboard wiring 152; to the right speaker 141 and the left speaker 142 through speaker wiring 143; to the camera 260 through camera wiring 151; to the input power receptacle 149 through input power wiring 145; to the docking connector 222 through PC board to tablet computer wiring. The input power receptacle 149 connects directly on one side to the PC board 144 through the input power wiring 145, and on the other side attaches directly and connects electrically to the input power plug 601. The input power plug 601 attaches directly and connects electrically on one side to the input power receptacle 149, and on the other side connects directly to the transformer connector 603 through the external power wiring 602. The transformer connector 603 connects directly on one side to the input power plug 601 through the external power wiring 602, and attaches directly and connects electrically to the transformer with AC power plug 604. The transformer with AC power plug 604 connects directly on one side to the transformer connector 603, and is directly connectable to the power outlet 605.

The PC board 144 can also be connected to a removable data storage device, such as a flash memory stick, to facilitate transfer of data from and to the tablet computer. Said removable data storage device can interface by means of a standard USB protocol or other data communication means to the tablet computer and also to other computer systems when said removable data storage device is removed from base member 100.

What is claimed is:

1. A carrying case for a tablet computer comprising:
a base member including a keyboard;
a frame member having provision for mounting said tablet computer pivotally coupled to said base member;
an electrical communication means between said tablet computer and said keyboard;
a rear support member having a major flat surface pivotally coupled to said frame member, and;
a pivotal motion limiting means that limits said pivotal motion of said rear support member relative to said frame member.

2. The carrying case of claim 1 wherein said pivotal motion limiting means includes:
a link member having both a pivot axis and a linear motion axis, said link member being pivotally connected to said frame member about said pivot axis, and;
a linear motion guide means that constrains the motion of said linear motion axis to a plane parallel to said major flat surface of said rear support member.

3. The carrying case of claim 1 wherein said electrical communications means includes:
an electrical connector attached to said frame member;
said electrical connector inserting into said tablet computer when said tablet computer is mounted into said frame member, and;
electrical wiring that connects said electrical connector to said keyboard.

4. The carrying case of claim 3 wherein said electrical connector is pivotally mounted to said frame member.

5. The carrying case of claim 1 wherein:
said base includes a trackpad as well as said keyboard, and;
said trackpad is in electrical communication with said tablet computer when said tablet computer is mounted into said frame member.

6. The carrying case of claim 5 wherein said electrical communications means includes:
an electrical connector attached to said frame member, where said electrical connector inserts into said tablet computer when said tablet computer is mounted into said frame member;
electrical wiring that connects said electrical connector to said keyboard, and;
trackpad electrical wiring that connects said electrical connector to said trackpad.

7. The carrying case of claim 6 wherein said electrical connector is pivotally mounted to said frame member.

8. The carrying case of claim 1 wherein said electrical communications means includes a bidirectional radio circuit attached to said keyboard.

9. The carrying case of claim 8 further comprising a removable keyboard housing wherein said keyboard and said bidirectional radio circuit are housed together and can be removed from said base member.

10. The carrying case of claim 1 further comprising:
a solar panel mounted to said rear support member;
an electrical connector attached to said frame member, where said electrical connector inserts into said tablet computer when said tablet computer is mounted into said frame member, and;
solar panel electrical wiring that connects said electrical connector to said solar panel.

11. The carrying case of claim 10 additionally comprising a battery connected to said solar panel.

12. The carrying case of claim 1 wherein said frame member includes a tablet computer retaining means.

13. The carrying case of claim 12 wherein said tablet computer retaining means includes at least one spring.

14. The carrying case of claim 1, further comprising:
a latching means that maintains said carrying case in a closed configuration until manually acted on to release said latching means.

15. The carrying case of claim 14 wherein said latching means includes at least one magnet.

16. The carrying case of claim 1, further comprising a flash drive, removably attached to said carrying case, said flash drive in electrical communication with tablet computer when said tablet computer is mounted to said frame member and said flash drive is mounted to said tablet computer.

17. The carrying case of claim 1, further comprising at least one digital camera, attached to said carrying case, said camera in electrical communication with tablet computer when said tablet computer is mounted to said frame member.

18. The carrying case of claim 1, further comprising at least one speaker, attached to said carrying case, said speaker in electrical communication with tablet computer when said tablet computer is mounted to said frame member.

19. The carrying case of claim 1, further comprising at least one microphone, attached to said carrying case, said microphone in electrical communication with tablet computer when said tablet computer is mounted to said frame member.

20. The carrying case of claim 1, further comprising a charging port, attached to said carrying case, said charging port in electrical communication with tablet computer when said tablet computer is mounted to said frame member.

21. The carrying case of claim 20, further comprising a battery, wherein said charging port is in electrical communication with said battery.

22. The carrying case of claim 1, further comprising a external data port, attached to said carrying case, said data port in electrical communication with tablet computer when said tablet computer is mounted to said frame member.

23. The carrying case of claim 1, further comprising at least one manually operated electrical switch, attached to said carrying case, said switch in electrical communication with tablet computer when said tablet computer is mounted to said frame member.

24. The carrying case of claim 1, further comprising a position sensor, attached to said carrying case, said position sensor in electrical communication with tablet computer when said tablet computer is mounted to said frame member, where position sensor indicates to said tablet computer whether said case is in the open or the closed configuration.

25. The carrying case of claim 24 wherein said position sensor includes at least one magnet.

26. The carrying case of claim 1, further comprising a charge condition indicator, attached to said carrying case, said indicator in electrical communication with tablet computer when said tablet computer is mounted to said frame member.
